(19) United States
(12) Patent Application Publication
(10) Pub. No.: US 2024/0258120 A1
(43) Pub. Date: Aug. 1, 2024

(54) LASER-CUT LEAD FRAME FOR INTEGRATED CIRCUIT (IC) PACKAGES

(71) Applicant: TEXAS INSTRUMENTS INCORPORATED, DALLAS, TX (US)

(72) Inventors: Yuntao XU, CHENGDU (CN); Li Xiang ZHENG, CHENGDU (CN); Chin Sern Alex TING, IPOH (MY); Chong Han LIM, SELANGOR (MY)

(21) Appl. No.: 18/162,294

(22) Filed: Jan. 31, 2023

(51) Int. Cl. H01L 21/48; H01L 21/56; H01L 23/00; H01L 23/31; H01L 23/495

(52) U.S. Cl. CPC H01L 21/4842; H01L 21/561; H01L 23/3107; H01L 23/49541; H01L 24/96; H01L 2224/96

(57) ABSTRACT

One example described herein includes a method for fabricating integrated circuit (IC) packages. The method includes providing an incomplete lead frame portion and laser-cutting the incomplete lead frame portion to provide a completed lead frame sheet. The completed lead frame sheet includes through-holes and three-dimensional step features. The method further includes coupling a plurality of IC dies to the completed lead frame sheet and coupling the completed lead frame sheet and the IC dies to packaging material to form an IC package block comprising the IC packages.

### TECHNICAL FIELD

This description relates generally to electronic circuits, and more particularly to a laser-cut lead frame for integrated circuit (IC) packages.

### BACKGROUND

Integrated circuits (ICs) form the basis for modern computing, in which IC dies are fabricated based on etching and layering different materials. The IC dies are combined with conductive metal that forms ground pads and leads and are packaged in packaging material to form IC packages. The conductive metal for a set of semiconductor dies that correspond to multiple IC dies can be formed from a lead frame. Typically, a lead frame is etched in a similar manner as a semiconductor wafer to form the divisions and separations that can facilitate coupling of the ground pads and leads to the respective IC dies. The etching process typically involves deposition of chemicals that dissolve portions of the conductive metal to form holes that result in the divisions and separations that allow for the entire lead frame to be coupled to the semiconductor dies and for the semiconductor dies and lead frame to be coupled to the packaging material to form a block of IC packages. The IC packages in the IC package block are thus mechanically separated (e.g., by a sawing process) to singulate the IC packages in a typical fabrication process.

### SUMMARY

One example described herein includes a method for fabricating integrated circuit (IC) packages. The method includes providing an incomplete lead frame portion and laser-cutting the incomplete lead frame portion to provide a completed lead frame sheet. The completed lead frame sheet comprising through-holes and three-dimensional step features. The method includes coupling a plurality of IC dies to the completed lead frame sheet, and coupling the completed lead frame sheet and the IC dies to packaging material to form an IC package block comprising the IC packages.

Another example described herein includes a method for fabricating integrated circuit (IC) packages. The method includes providing an incomplete lead frame portion comprising through-holes and laser-cutting three-dimensional step features on the incomplete lead frame portion to form a completed lead frame sheet. The method includes coupling a plurality of IC dies to the completed lead frame sheet, and coupling the completed lead frame sheet and the IC dies to packaging material to form an IC package block comprising the IC packages.

Another example described herein includes a method for fabricating integrated circuit (IC) packages. The method includes providing an incomplete lead frame portion comprising three-dimensional step features and laser-cutting through-holes in the incomplete lead frame portion to form a completed lead frame sheet. The method includes coupling a plurality of IC dies to the completed lead frame sheet, and coupling the completed lead frame sheet and the IC dies to packaging material to form an IC package block comprising the IC packages.

Another example described herein includes an IC package. The IC package includes an IC and a ground pad formed from a lead frame that is provided from part of a completed lead frame sheet. The completed lead frame sheet can be formed from laser-cutting an incomplete lead frame portion to provide the completed lead frame sheet. The completed lead frame sheet can include through-holes and three-dimensional step features. The IC package also includes a plurality of leads formed from the lead frame. The IC package further includes packaging material that substantially surrounds the IC and a portion of each of the ground pad and the plurality of leads.

### BRIEF DESCRIPTION OF THE DRAWINGS

FIG. 1 is an example of a block diagram of a process for fabricating IC packages.

FIG. 2 is an example diagram of a completed lead frame sheet.

FIG. 3 is an example diagram of a process for providing a completed lead frame sheet.

FIG. 4 is another example diagram of a process for providing a completed lead frame sheet.

FIG. 5 is an example of a completed lead frame sheet.

FIG. 6 is an example of a process for singulating IC packages.

FIGS. 7A & 7B are example diagrams of singulated IC packages.

FIGS. 8A, 8B, and 8C are example diagrams of an IC package.

FIG. 9 is an example of an IC package.

FIGS. 10A & 10B are other example diagrams of an IC package.

FIG. 11 is an example of a method for fabricating IC packages.

### DETAILED DESCRIPTION

This description relates generally to electronic circuits, and more particularly to a laser-cut lead frame for integrated circuit (IC) packages. A lead frame can include the distinctive features of through-holes and three-dimensional step features that are formed during fabrication. As described herein, the lead frame can be fabricated in a two-step process. The first step includes providing an incomplete lead frame portion from a conductive metal material sheet, and the second step includes laser-cutting the incomplete lead frame portion to form a completed lead frame sheet. As described herein, the term “incomplete lead frame portion” describes a lead frame that has been only partially formed, such that the lead frame is completed based on the subsequent laser-cutting process. The conductive metal material sheet can correspond to any of a variety of conductive metals (e.g., copper, aluminum, etc.) that can be used to form the lead frame, and thus the conductive components of the IC packages (e.g., ground pads, signal pads, pins, leads, etc.).

As a first example, the incomplete lead frame portion can be formed by implementing a punch press on the conductive metal material sheet to form through-holes in the conductive metal material sheet. Therefore, the punched conductive metal material sheet can correspond to the incomplete lead frame portion having the through-holes. The incomplete lead frame portion can thus have a length and width that are approximately the same as the conductive metal material sheet (e.g., less through-holes at edges), and can have a thickness that is approximately uniform across the incomplete lead frame portion. The incomplete lead frame portion can thus be laser-cut to form the three-dimensional step features. For example, the laser-cutting can include laser ablation to selectively carve portions of the thickness of the incomplete lead frame portion to provide first portions of the completed lead frame sheet having a first thickness and second portions of the completed lead frame sheet having a second thickness that is less than the first thickness. The variability of the thickness of the completed lead frame sheet between the first and second thicknesses can thus correspond to the three-dimensional step features.

As a second example, the incomplete lead frame portion can be formed by implementing a chemical etching process (e.g., as provided in typical IC fabrication processes) on the conductive metal material sheet to form first portions of the incomplete lead frame portion having a first thickness and second portions of the incomplete lead frame portion having a second thickness that is less than the first thickness. Therefore, the etched conductive metal material sheet can correspond to the incomplete lead frame portion having the three-dimensional step features. The incomplete lead frame portion can thus have a length and width that are approximately the same as the conductive metal material sheet (e.g., less through-holes at edges), and can have a thickness that varies between the first and second thicknesses across the incomplete lead frame portion. Portions of the second thickness of the incomplete lead frame portion can thus be laser-cut to form the through-holes. For example, the laser-cutting can include laser ablation to selectively carve the second portions of the incomplete lead frame portion having the second thickness to provide the through-holes in the completed lead frame sheet.

Therefore, as described herein, the lead frame can be laser-cut to include all of the features of a lead frame that is typically etched, such as including through-holes, three-dimensional step features for mating with corresponding holes in packaging material of an IC package (e.g., a quad flat no-lead (QFN) IC package). As another example, the lead frame can also include additional features associated with lead frames, such as an index through-hole, a mold-flow vent feature, and a stress-release feature. The lead frame can thus be fabricated with a laser-cutting process on a conductive metal material sheet to include all of the features of a typical etched lead frame.

IC dies can be coupled to the lead frame and to the packaging material to form an IC package block. The IC package block can thus include a plurality of IC packages that are conjoined by the packaging material and the lead frame. The IC packages can thus be singulated based on laser-cutting the IC package block, as opposed to a typical fabrication process in which the IC package block is mechanically cut (e.g., with a saw or other cutting tool). Such mechanical cutting for a typical fabrication procedure is provided along a tie-bar, which is typically required for an etched lead frame. However, laser-cutting the lead frame can obviate the need for tie-bars and cross-bars in the lead frame, thus facilitating a simpler arrangement for the lead frame and a cleaner singulation of the IC packages from the IC package block. Furthermore, one or more grooves can be laser-cut in the packaging material and the lead frame of each of the IC packages (e.g., a bottom surface of the IC packages) to electrically isolate portions of the lead frame from each other. For example, the groove(s) can isolate a plurality of leads from the ground pad in each of the IC packages. As described herein, the term “leads” can refer to signal pads, such as in the example of the IC packages being arranged as QFN IC packages.

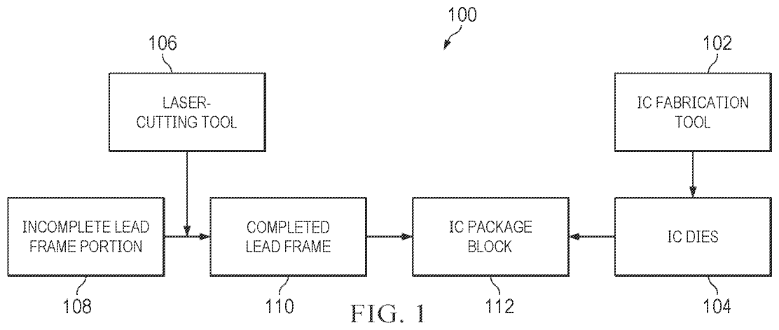

FIG. 1 is an example of a block diagram 100 of a process for fabricating integrated circuit (IC) packages. The diagram 100 can correspond to a simplistic example of fabrication of any of a variety of different types of IC packages. As an example, the IC packages can be fabricated as quad flat no-lead (QFN) IC packages.

The diagram 100 includes an IC fabrication tool 102 that is configured to fabricate a plurality of IC dies 104, such as on a semiconductor wafer. For example, the IC fabrication tool 102 can be configured to provide material deposition, chemical etching, and a variety of other IC fabrication processes to fabricate the IC dies 104 on the semiconductor wafer. As an example, the semiconductor wafer can include a substrate (e.g., formed from any of a variety of substrate materials) on which the IC dies 104 are fabricated.

The diagram 100 also includes a laser-cutting tool 106 that is configured to laser-cut an incomplete lead frame portion 108. The laser-cutting tool 106 can correspond to any of a variety of graphical lasers that provide sufficient power to cut through the materials of an IC package (e.g., silicon, metal, plastic, etc.), such as via laser ablation, as described in greater detail herein. For example, the incomplete lead frame portion 108 can be formed from a conductive metal material sheet (e.g., a copper or aluminum sheet) and includes either through-holes or three-dimensional step features. The laser-cutting tool 106 can therefore form the other of the through-holes and three-dimensional step features into the incomplete lead frame portion 108 to form a completed lead frame sheet 110. As another example, the laser-cutting tool 106 can also cut additional features associated with a traditional lead frame into the incomplete lead frame portion 108 to form the completed lead frame sheet 110, such as a groove in the incomplete lead frame portion 108 and/or a fused lead in the incomplete lead frame portion 108, as described in greater detail herein.

As a first example, the incomplete lead frame portion 108 can be formed by implementing a punch press on the conductive metal material sheet to form through-holes in the conductive metal material sheet. Therefore, the punched conductive metal material sheet can correspond to the incomplete lead frame portion 108 having the through-holes. The incomplete lead frame portion 108 can thus have a length and width that are approximately the same as the conductive metal material sheet (e.g., less through-holes at edges), and can have a thickness that is approximately uniform across the incomplete lead frame portion 108. The incomplete lead frame portion 108 can thus be laser-cut to form the three-dimensional step features. For example, the laser-cutting can include laser ablation to selectively carve portions of the thickness of the incomplete lead frame portion 108 to provide first portions of the completed lead frame sheet 110 having a first thickness and second portions of the completed lead frame sheet 110 having a second thickness that is less than the first thickness. The variability of the thickness of the completed lead frame sheet 110 between the first and second thicknesses can thus correspond to the three-dimensional step features.

As a second example, the incomplete lead frame portion 108 can be formed by implementing a chemical etching process (e.g., as provided in typical IC fabrication processes) on the conductive metal material sheet to form first portions of the incomplete lead frame portion 108 having a first thickness and second portions of the incomplete lead frame portion 108 having a second thickness that is less than the first thickness. Therefore, the etched conductive metal material sheet can correspond to the incomplete lead frame portion 108 having the three-dimensional step features. The incomplete lead frame portion 108 can thus have a length and width that are approximately the same as the conductive metal material sheet (e.g., less through-holes at edges), and can have a thickness that varies between the first and second thicknesses across the incomplete lead frame portion 108. Portions of the second thickness of the incomplete lead frame portion 108 can thus be laser-cut to form the through-holes. For example, the laser-cutting can include laser ablation to selectively carve the second portions of the incomplete lead frame portion 108 having the second thickness to provide the through-holes in the completed lead frame sheet 110.

In the example of FIG. 1, the completed lead frame sheet 110 is combined with the IC dies 104, which can be previously singulated from a semiconductor wafer (e.g., via the laser-cutting tool 106 or another cutting tool), to form an IC package block 112. As an example, the IC package block 112 can also include packaging material (not shown), such as a plastic molding material, that can substantially surround the singulated IC dies 104 and can surround portions of the incomplete lead frame portion 108 to form IC package block 112. Therefore, the IC package block 112 can correspond to a group of IC packages that are conjoined by the completed lead frame sheet 110 and the packaging material. As described in greater detail herein, the completed lead frame sheet 110 thus provides multiple lead frames that each include at least one ground pad and a plurality of leads for each of the IC packages in the IC package block 112.

As described herein, implementing laser-cutting to form the completed lead frame sheet 110 provides for a significantly more efficient and cost-effective manner of fabricating the incomplete lead frame portion 108, and by extension the IC package block 112, than a typical manner of fabricating a lead frame. Typical lead frames are fabricated entirely based on an etching (e.g., chemical etching) process. Chemical etching can result in a much less precise shaping of through-holes, such as to be unable to provide tight tolerances often required for smaller chip designs. For example, etching a lead frame sheet in its entirety can limit a minimum size of a given IC and a given input/output (I/O) count, for a given lead frame of the incomplete lead frame portion 108, based on imprecise etching tolerance and a minimum etching space, thereby limiting meeting the demand for miniaturization of IC packages. Additionally, etching lead frames entirely can be significantly more expensive than laser-cutting the incomplete lead frame portion 108. For example, the etching process can be more costly and can take a significantly longer time to complete than programming the laser-cutting tool 106. However, by implementing an in-house laser-cutting tool 106 to finish the fabrication of an incomplete lead frame portion 108, such delays and costs can be greatly mitigated. For these reasons, laser-cutting the incomplete lead frame portion 108 via the laser-cutting tool 106 to form the completed lead frame sheet 110 can provide for a significantly more efficient fabrication process than etching a lead frame.

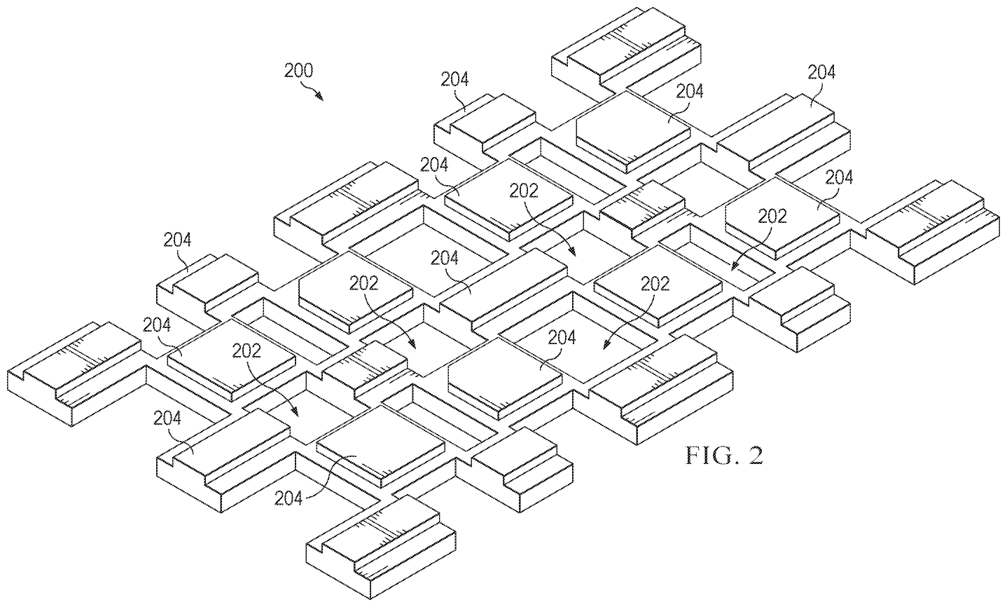

FIG. 2 is an example diagram of a completed lead frame sheet 200. As an example, the completed lead frame sheet 200 can be formed initially from a conductive metal material sheet, such as a thin sheet of copper or other conductive metal that can be cut and shaped via a laser (e.g., the laser-cutting tool 106). The completed lead frame sheet 200 is demonstrated as including through-holes 202 and three-dimensional step features 204. In the example of FIG. 2, the three-dimensional step features 204 are demonstrated as partial removal of the thickness of the conductive metal material sheet, such that the three-dimensional step features 204 include thinner portions of the completed lead frame sheet 200.

The three-dimensional step features 204 can facilitate coupling of the completed lead frame sheet 200 with packaging material, such that a portion of the completed lead frame sheet 200 in a resulting IC package can be exposed while the remainder of the completed lead frame sheet 200 can be surrounded by and held in place by the packaging material. Therefore, as described in greater detail herein, the completed lead frame sheet 200 can form lead frames that include ground pads and leads of the resultant IC packages. The three-dimensional step features 204 can also provide stress-release for the resulting IC packages. Furthermore, the completed lead frame sheet 200 can include additional features that are formed by the laser-cutting tool 106, such as index through-holes and/or mold-flow vent features. As an example, the packaging material can be formed by a plastic molding material that is flowed onto the combined completed lead frame sheet 200 and respective IC dies (e.g., via an injection molding process), followed by a post-mold cure (PMC) process.

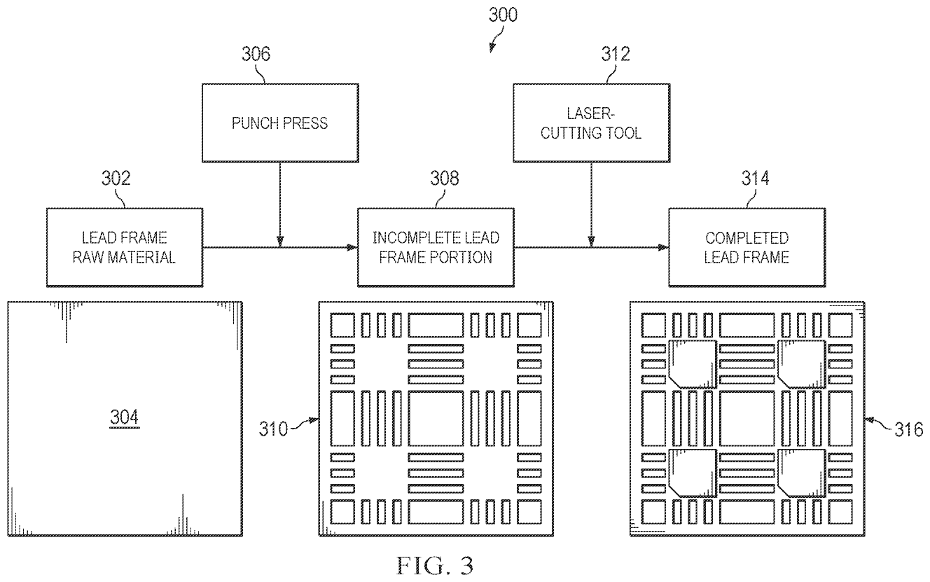

FIG. 3 is an example diagram 300 of a process for providing a completed lead frame sheet. The diagram 300 is directed to a first example as to how a completed lead frame sheet is formed from an incomplete lead frame portion.

The diagram 300 demonstrates a conductive metal material sheet 302, also demonstrated in a pictorial plan view at 304. The conductive metal material sheet 302 can be a sheet of conductive metal material having a length, a width, and a uniform thickness (e.g., a thickness of approximately 5 to 6 mil). As an example, the conductive metal material sheet can be formed from copper, aluminum, or any of a variety of other conductive metals that can be provided in IC packages (e.g., for ground and signal pads, pins, etc.). A punch press 306 is implemented on the conductive metal material sheet 302 to form an incomplete lead frame portion 308, also demonstrated in a pictorial plan view at 310. The punch press 306 is thus configured to form through-holes having predefined patterns, shapes, and dimensions in the conductive metal material sheet 302 to form the incomplete lead frame portion 308. For example, the through-holes can correspond to gaps between pins, leads, ground pads, signal pads, or other metallized structures in the resultant IC packages. The plan view 310 is demonstrated by example to illustrate holes of varying dimensions between portions of metal having an approximately uniform thickness. The incomplete lead frame portion 308 can thus have a length and width that are approximately the same as the conductive metal material sheet 302 (e.g., less through-holes at edges), and can have a thickness that is approximately uniform across the incomplete lead frame portion 308.

The diagram 300 also demonstrates a laser-cutting tool 312 that is configured to laser-cut the incomplete lead frame portion 308. The laser-cutting tool 312 can correspond to any of a variety of graphical lasers that provide sufficient power to cut through the materials of an IC package (e.g., silicon, metal, plastic, etc.), such as via laser ablation. In the example of FIG. 3, the laser-cutting tool 312 is configured to selectively carve portions of the thickness of the incomplete lead frame portion 308 to form three-dimensional step features in a completed lead frame sheet 314, also demonstrated in a pictorial plan view at 316. For example, the laser-cutting tool 312 can provide first portions of the completed lead frame sheet 314 having a first thickness and second portions of the completed lead frame sheet 314 having a second thickness that is less than the first thickness (e.g., approximately half the first thickness). The variability of the thickness of the completed lead frame sheet 314 between the first and second thicknesses can thus correspond to the three-dimensional step features.

In the example of FIG. 3, the darker shaded portions of the conductive metal material sheet 302, the incomplete lead frame portion 308, and the completed lead frame sheet 314 correspond to the first thickness, and the lighter shaded portions of the completed lead frame sheet 314 correspond to the second thickness that is less than the first thickness. As another example, the laser-cutting tool 312 can also cut additional features associated with a traditional lead frame into the incomplete lead frame portion 308 to form the completed lead frame sheet 314, such as a groove in the incomplete lead frame portion 308. The portions of the completed lead frame sheet 314 that are demonstrated as having the respective first and second thicknesses can vary greatly, and are demonstrated in the example of FIG. 3 as but one example.

The completed lead frame sheet 314 can thus be combined with IC dies, which can be previously singulated from a semiconductor wafer, such as to form the IC package block 112 in the example of FIG. 1. Therefore, the IC package block 112 can correspond to a group of IC packages that are conjoined by the completed lead frame sheet 110 and the packaging material. Accordingly, the completed lead frame sheet 314 provides multiple lead frames that each include at least one ground pad and a plurality of leads for each of the IC packages in the IC package block 112.

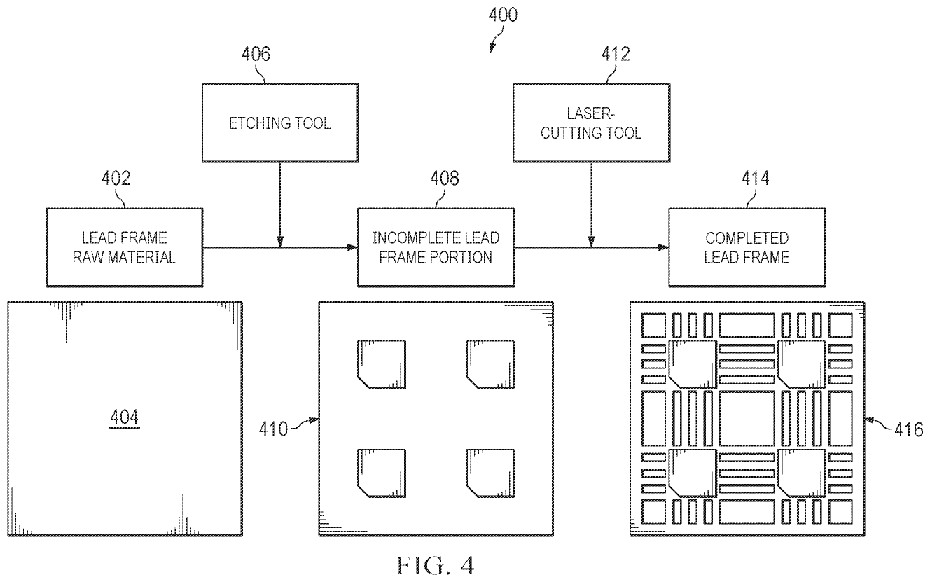

FIG. 4 is an example diagram 400 of a process for providing a completed lead frame sheet. The diagram 400 is directed to a second example as to how a completed lead frame sheet is formed from an incomplete lead frame portion.

The diagram 400 demonstrates a conductive metal material sheet 402, also demonstrated in a pictorial plan view at 404. The conductive metal material sheet 402 can be a sheet of conductive metal material having a length, a width, and a uniform thickness (e.g., a thickness of approximately 5 to 6 mil). An etching tool 406 is implemented on the conductive metal material sheet 402 to form an incomplete lead frame portion 408, also demonstrated in a pictorial plan view at 410. The etching tool 406 is thus configured to provide chemical etching of portions of the conductive metal material sheet 402 to form three-dimensional step features having predefined patterns, shapes, and dimensions in the conductive metal material sheet 402 to form the incomplete lead frame portion 408. The plan view 410 is demonstrated by example to illustrate varying thickness across the incomplete lead frame portion 408. For example, the three-dimensional step features can correspond to first portions of the incomplete lead frame portion 408 having a first thickness and second portions of the incomplete lead frame portion 408 having a second thickness that is less than the first thickness (e.g., approximately half the first thickness). The variability of the thickness of the completed lead frame sheet 414 between the first and second thicknesses can thus correspond to the three-dimensional step features. The incomplete lead frame portion 408 can thus have a length and width that are approximately the same as the conductive metal material sheet 402 (e.g., less through-holes at edges), and can have a thickness that varies between the first and second thicknesses across the incomplete lead frame portion 408.

The diagram 400 also demonstrates a laser-cutting tool 412 that is configured to laser-cut the incomplete lead frame portion 408. The laser-cutting tool 412 can correspond to any of a variety of graphical lasers that provide sufficient power to cut through the materials of an IC package (e.g., silicon, metal, plastic, etc.), such as via laser ablation. In the example of FIG. 4, the laser-cutting tool 412 is configured to selectively carve portions of the second (e.g., thinner) thickness of the incomplete lead frame portion 408 to form through-holes in a completed lead frame sheet 414, also demonstrated in a pictorial plan view at 416. For example, the laser-cutting tool 412 can cut through predefined portions of the second thickness of the incomplete lead frame portion 408 to provide the through-holes in predefined patterns, shapes, and dimensions.

In the example of FIG. 4, the darker shaded portions of the conductive metal material sheet 402, the incomplete lead frame portion 408, and the completed lead frame sheet 414 correspond to the first thickness, and the lighter shaded portions of the completed lead frame sheet 414 correspond to the second thickness that is less than the first thickness. As another example, the laser-cutting tool 412 can also cut additional features associated with a traditional lead frame into the incomplete lead frame portion 408 to form the completed lead frame sheet 414, such as a groove in the incomplete lead frame portion 408.

The completed lead frame sheet 414 can thus be combined with IC dies, which can be previously singulated from a semiconductor wafer, such as to form the IC package block 112 in the example of FIG. 1. Therefore, the IC package block 112 can correspond to a group of IC packages that are conjoined by the completed lead frame sheet 110 and the packaging material. Accordingly, the completed lead frame sheet 414 provides multiple lead frames that each include at least one ground pad and a plurality of leads for each of the IC packages in the IC package block 112.

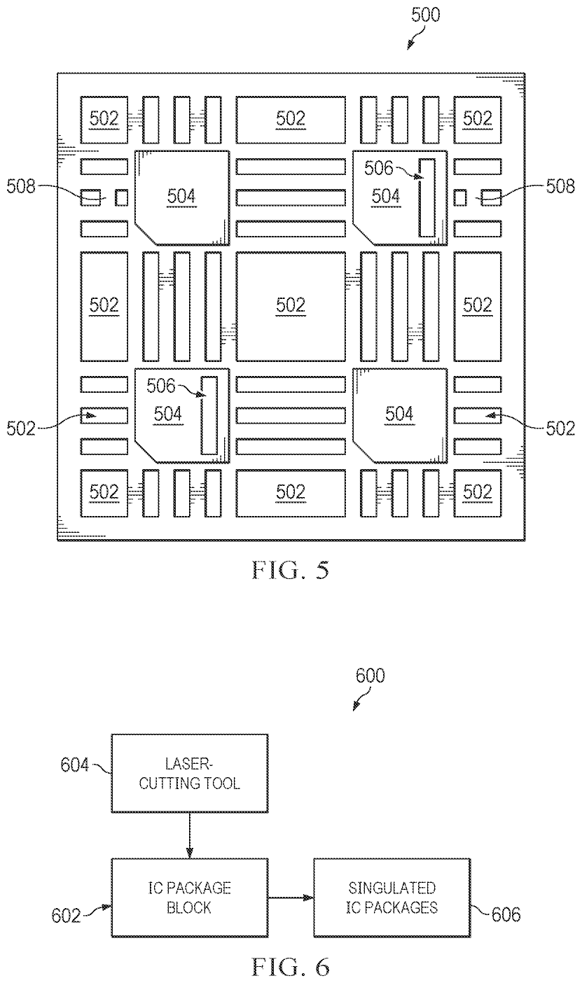

FIG. 5 is an example of a completed lead frame sheet 500. The completed lead frame sheet 500 can correspond to the completed lead frame sheet 314 or the completed lead frame sheet 414 in the respective examples of FIGS. 3 and 4. Therefore, reference is to be made to the examples of FIGS. 3 and 4 in the following description of the example of FIG. 5.

The completed lead frame sheet 500 can include through-holes 502 and three-dimensional step features 504, similar to as described above. The three-dimensional step features 504 are illustrated as transitions between the first thickness (e.g., the darker shading) and the second thickness (e.g., the lighter shading). As an example, the completed lead frame sheet 500 can be formed from an incomplete lead frame portion that includes the through-holes 502, such as formed from the punch press 306, such that the laser-cutting tool 312 forms the three-dimensional step features 504 by cutting away at the first thickness to form portions of the completed lead frame sheet 500 that have the second thickness. As another example, the completed lead frame sheet 500 can be formed from an incomplete lead frame portion that includes the three-dimensional step features 504, such as formed from the etching tool 406, such that the laser-cutting tool 412 forms the through-holes 502 by cutting through predefined portions of the second thickness.

In addition, the completed lead frame sheet 500 can include additional features that can be formed by the laser-cutting tool, such as after or concurrently with the formation of the through-holes 502 or the three-dimensional step features 504. In the example of FIG. 5, the completed lead frame sheet 500 includes grooves 506 that are cut into the first thickness portions of the completed lead frame sheet 500. The grooves 506 can provide any of a variety of functions, such as to form provide relief of physical stress, to allow the filling of molding material, or a variety of other functions. The grooves 506 can therefore be formed at any time on the incomplete lead frame portion or the resultant completed lead frame sheet 500 in a flexible manner.

In the example of FIG. 5, the completed lead frame sheet 500 also includes fused leads 508 that are demonstrated as portions of the second thickness of the completed lead frame sheet 500 that join two adjacent leads of the completed lead frame sheet 500. As an example, in response to providing the incomplete lead frame portion 408 that includes the three-dimensional step features, the laser-cutting tool 412 can cut only a portion of the material of the second thickness between adjacent leads to form the fused leads 508. The fused leads 508 can therefore be formed at any time on the incomplete lead frame portion or the resultant completed lead frame sheet 500 in a flexible manner.

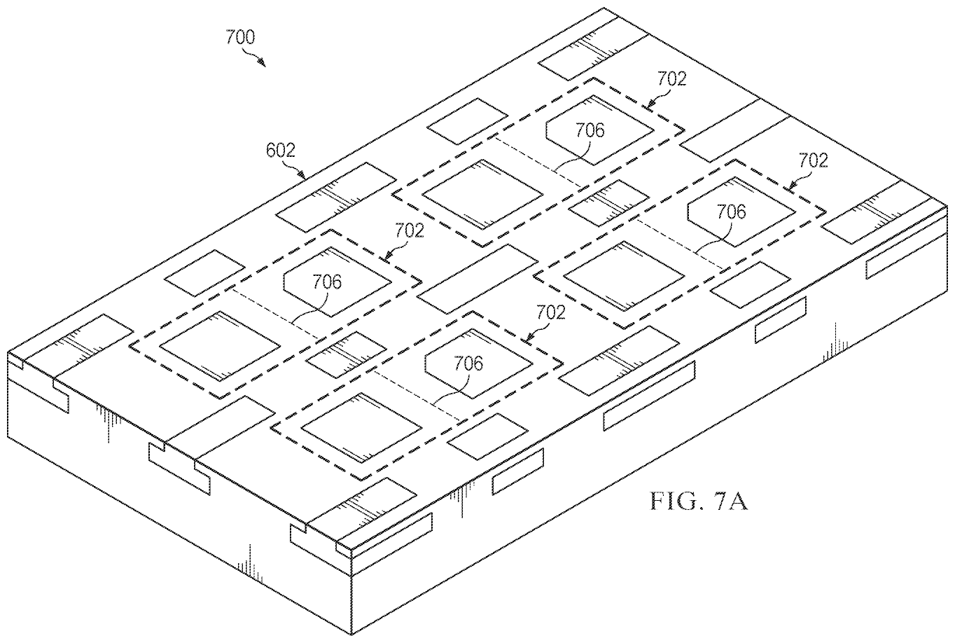

FIG. 6 is another example of a block diagram 600 of a process for fabricating IC packages. The diagram 600 can correspond to a simplistic example of fabrication of any of a variety of different types of IC packages. As an example, the diagram 600 can correspond to a portion of the fabrication process subsequent to the formation of the IC package block, demonstrated in the example of FIG. 6 at 602.

The diagram 600 also includes a laser-cutting tool 604. As an example, the laser-cutting tool 604 can correspond to the same laser-cutting tool 106 demonstrated in the example of FIG. 1, or the laser-cutting tool 312 or 412 in the respective examples of FIGS. 3 and 4. Therefore, as described in greater detail herein, the laser-cutting tool 604 can be used for multiple stages and functions during the fabrication of the IC packages. In the example of FIG. 6, the laser-cutting tool 604 is provided to the IC package block 602 to cut around each of the IC packages that are conjoined together on the IC package block 602. As a result, the laser-cutting tool 604 can singulate the IC packages as discrete IC packages relative to each other, thus providing singulated IC packages 606. Therefore, as opposed to implementing a mechanical separation of the IC packages, as is provided in a typical fabrication process, the laser-cutting tool 604 can laser-cut the IC package block 602 to provide the singulated IC packages 606. In addition, as described in greater detail herein, the laser-cutting tool 604 can cut one or more trenches into each of the IC packages (e.g., before or after singulation) to electrically isolate portions of the completed lead frame sheet (e.g., the completed lead frame sheets 200, 314, 414, or 500). Therefore, the trench(es) can form the ground pads and the leads of each of the IC packages from the completed lead frame sheet.

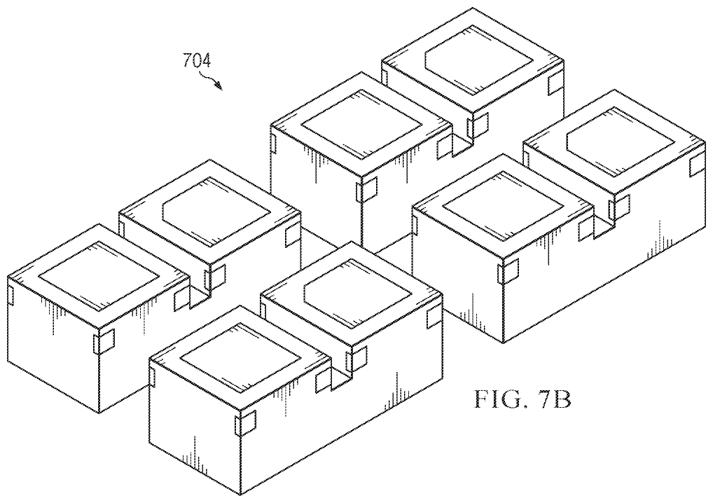

FIGS. 7A and 7B demonstrate example diagrams of singulated IC packages. FIG. 7A demonstrates a diagram 700 that includes the IC package block 602 in the example of FIG. 6. Therefore, the IC package block 602 is demonstrated as the combination of the IC dies, the completed lead frame sheet, and packaging material. In the example of FIG. 7A, the IC package block 602 is marked with dashed lines 702 to demonstrate the borders of IC packages, demonstrated in the example of FIG. 7B as IC packages 704. As an example, the laser-cutting tool 604 can cut along the dashed lines 702 to singulate the IC chips in the IC package block 602 to provide the IC packages 704. Additionally, the IC package block 602 is marked with dotted lines 706 that can correspond to a location of a trench that the laser-cutting tool 604 can cut into each of the IC packages 704. The trench can correspond to a partial cut through the IC package block 602, as opposed to a through-cut that is implemented for the singulation of the IC packages 704. The trench along the dotted line 706 can thus be sufficient to cut through a portion of the completed lead frame sheet to electrically isolate portions of the lead frame of the resultant IC packages 704, thereby providing electrical isolation between leads a ground pad for each of the IC packages 704.

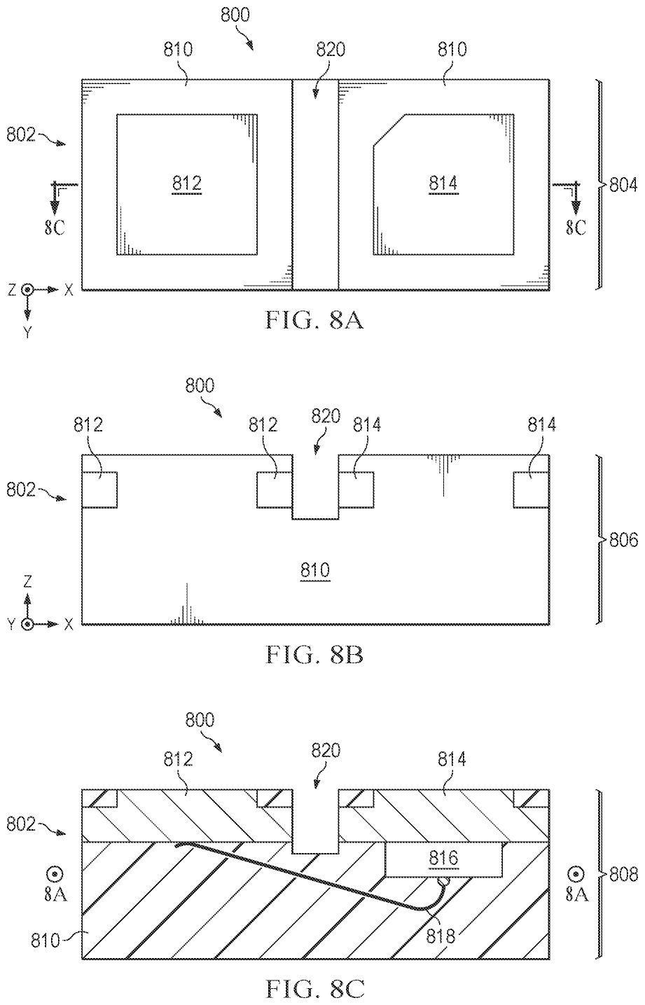

FIGS. 8A, 8B, and 8C are example diagrams 800 of an IC package 802. The diagrams 800 demonstrate three views of the IC package 802, including a first view 804 in FIG. 8A along an XY-plane of the IC package 802, a second view 806 in FIG. 8B along an XZ-plane of the IC package 802, and a third view 808 in FIG. 8C of the IC package 802 corresponding to a cross-sectional view taken along “8C” in the first view 804. The IC package 802 can correspond to one of the IC packages 704 in the example of FIG. 7B. Therefore, the IC package 802 can be formed from singulating the IC packages 704 in the IC package block 602 via the laser-cutting tool 604. As an example, the IC package 802 corresponds to a QFN IC package, with the first view 804 corresponding to a view of the bottom of the IC package 802.

The IC package 802 includes packaging material 810 (e.g., molding material, such as a polymer or epoxy) that substantially surrounds the portions of the lead frame, formed from the completed lead frame sheet (e.g., the completed lead frame sheets 200, 314, 414, or 500), which correspond to a first electrode 812 and a second electrode 814. As an example, one of the electrodes 812 and 814 can correspond to a ground pad and the other one of the electrodes 812 and 814 can correspond to a lead (or multiple leads, as dictating the laser-cutting tool 604). The packaging material 810 also surrounds an IC die 816 that can be directly conductively coupled to the second electrode 814, and is conductively coupled to the first electrode 812 via a conductive bond wire 818. As an example, the IC die 816 can be bonded and/or soldered to the lead frame from which the electrodes 812 and 814 are formed, such as prior to singulation. For example, the IC die 816 can be provided in a flip-chip arrangement to form the QFN IC package 802. While the example of FIGS. 8A, 8B, and 8C include the packaging material 810, the IC die 816 could instead be exposed.

The outer periphery of the packaging material 810 can thus be formed during the singulation of the IC package block 602 via the laser-cutting tool 604. In the example of FIGS. 8B and 8C, the first and second electrodes 812 and 814 are electrically isolated via a trench 820. As an example, the trench 820 can be formed by the laser-cutting tool 604, such that the first and second electrodes 812 and 814 can both initially be part of the laser-cut lead frame sheet 202, and can be separated by the laser-cutting tool 604 to electrically isolate the respective portions of the conductive metal of the resultant lead frame.

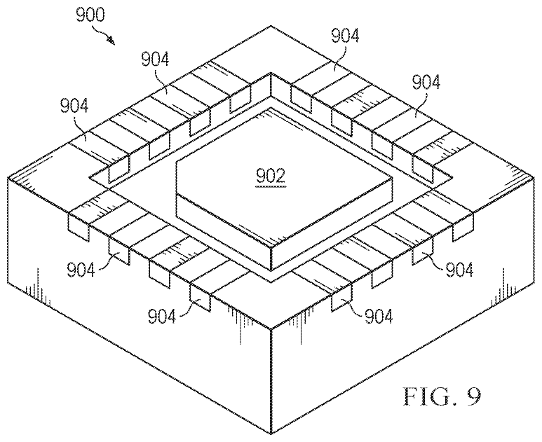

FIG. 9 is an example of a plan view of an IC package 900. The IC package 900 can correspond to another example of a QFN IC package. The IC package 900 includes a ground pad 902 and a plurality of leads 904 that are arranged along the periphery of the IC package 900. The ground pad 902 and the leads 904 can be electrically isolated via a trench that substantially surrounds the ground pad 902. As an example, the ground pad 902 can include one or more grooves, and one or more of the leads 904 can be fused, such as described above in the example of FIG. 5.

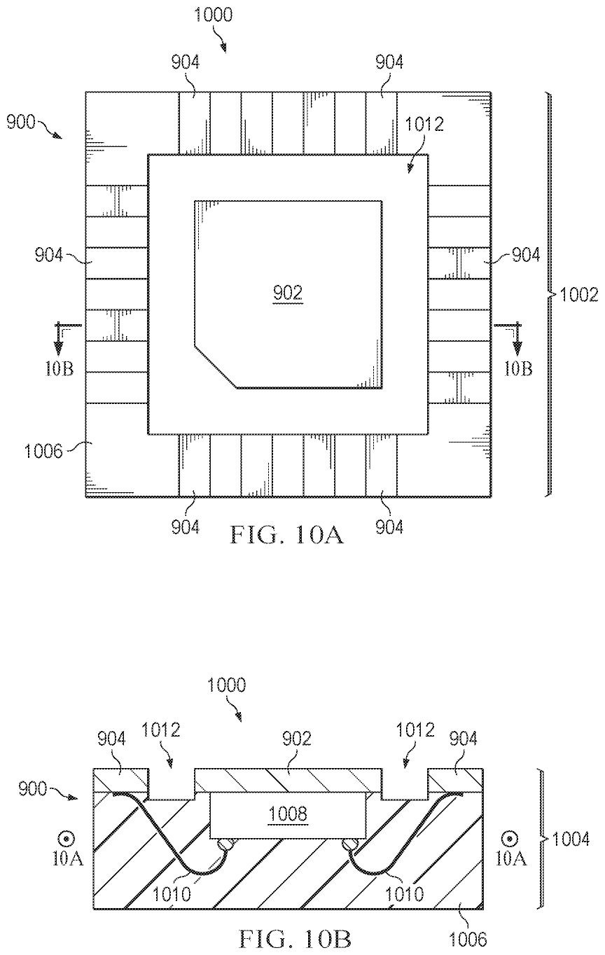

FIGS. 10A and 10B are example diagrams 1000 of the IC package 900. The diagrams 1000 demonstrates two views of the IC package 900, including a first view 1002 in FIG. 10A along an XY-plane of the IC package 900 and a second view 1004 in FIG. 10B of the IC package 900 corresponding to a cross-sectional view taken along “10B” in the first view 1002. Similar to as described above, the IC package 900 can be formed from singulating IC packages in an IC package block via the laser-cutting tool 604. As an example, the IC package 900 corresponds to a QFN IC package, with the first view 1002 corresponding to a view of the bottom of the IC package 900.

The IC package 900 includes packaging material 1006 that substantially surrounds the portions of the lead frame that correspond to the ground pad 902 and the leads 904. The packaging material 1006 also surrounds an IC die 1008 that is directly conductively coupled to the ground pad 902, and is conductively coupled to each of the leads 904 via conductive bond wires 1010. The outer periphery of the packaging material 1006 can thus be formed during the singulation of a respective IC package block via the laser-cutting tool 604. In the example of FIGS. 10A and 10B, the ground plane 902 and the leads 904 are electrically isolated via a trench 1012. As an example, the trench 1012 can be formed by the laser-cutting tool 604, such that ground plane 902 and the leads 904 can both initially be part of the laser-cut lead frame sheet 202, and can be separated by the laser-cutting tool 604 to electrically isolate the respective portions of the conductive metal of the resultant lead frame.

As an example, prior to forming the trench 1012, the IC package 900 (e.g., before or after singulation) can undergo an electrolytic plating process to deposit a corrosion-resistant material (e.g., Tin (Sn)) on the exposed portions of the lead frame or lead frame sheet 202 (e.g., external to the packaging material 810, such as the ground pad 902 and the plurality of leads 904). The electrolytic plating can substantially mitigate oxidization and/or corrosion of the material (e.g., Copper) that forms the lead frame sheet 202, and can also enable the IC package 900 to be mounted on a corresponding printed circuit board (PCB) by an end user of the IC package 900 (e.g., using a surface mount technology (SMT) process). Such an electrolytic plating process can be more cost effective than plating the entire conductive metal sheet with other materials (e.g., Nickel/Palladium/Gold) prior to laser-cutting the conductive metal material sheet 204 into the lead frame sheet 202, particularly when part of the plating is removed and wasted by forming the trench 1012.

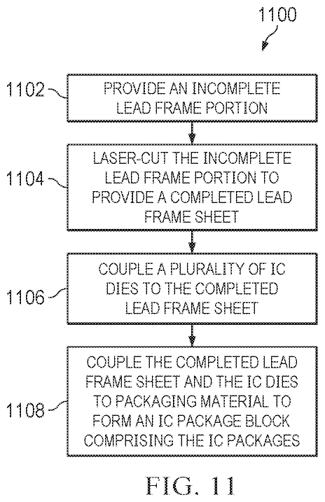

In view of the foregoing structural and functional features described above, a methodology in accordance with various aspects of the present invention will be better appreciated with reference to FIG. 11. While, for purposes of simplicity of explanation, the methodology of FIG. 11 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 11 is an example of a method 1100 for fabricating IC packages. At 1102, an incomplete lead frame portion (e.g., the incomplete lead frame portion 108) is provided. At 1104, the incomplete lead frame portion is laser-cut to form a completed lead frame sheet (e.g., the completed lead frame sheet 110). The completed lead frame sheet can include through-holes (e.g., the through-holes 502) and three-dimensional step features (e.g., the three-dimensional step features 504). At 1106, a plurality of IC dies are coupled to the completed lead frame sheet. At 1108, the completed lead frame sheet and the IC dies are coupled to packaging material to form an IC package block comprising the IC packages.

In this description, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A method for fabricating integrated circuit (IC) packages, the method comprising:
providing an incomplete lead frame portion;
laser-cutting the incomplete lead frame portion to provide a completed lead frame sheet, the completed lead frame sheet comprising through-holes and three-dimensional step features;
coupling a plurality of IC dies to the completed lead frame sheet; and
coupling the completed lead frame sheet and the IC dies to packaging material to form an IC package block comprising the IC packages.

2. The method of claim 1, wherein providing the incomplete lead frame portion comprises providing the incomplete lead frame portion comprising the through-holes.

3. The method of claim 1, wherein providing the incomplete lead frame portion comprises:
providing a conductive metal material sheet; and
implementing a punch press on the conductive metal material sheet to form the through-holes in the incomplete lead frame portion, the incomplete lead frame portion having a length and width approximately equal to the conductive metal material sheet and having an approximately uniform thickness.

4. The method of claim 3, wherein laser-cutting the incomplete lead frame portion comprises laser-cutting the incomplete lead frame portion to form the three-dimensional step features of the completed lead frame sheet.

5. The method of claim 1, wherein providing the incomplete lead frame portion comprises providing the incomplete lead frame portion comprising the three-dimensional step features.

6. The method of claim 1, wherein providing the incomplete lead frame portion comprises:
providing a conductive metal material sheet; and
performing an etching process on the conductive metal material sheet to form the three-dimensional step features on the incomplete lead frame portion, the incomplete lead frame portion having a length and width approximately equal to the conductive metal material sheet and having a thickness that varies to define the three-dimensional step features.

7. The method of claim 6, wherein laser-cutting the incomplete lead frame portion comprises laser-cutting the incomplete lead frame portion to form the through-holes of the completed lead frame sheet.

8. The method of claim 1, wherein laser-cutting the incomplete lead frame portion comprises forming at least one of a fused lead and a groove on a ground pad of the completed lead frame sheet.

9. The method of claim 1, further comprising laser-cutting the IC package block to singulate the IC packages.

10. The method of claim 1, wherein coupling the lead frame and the IC dies to the packaging material comprises coupling the lead frame and the IC dies to the packaging material to form the IC packages as quad flat no-lead (QFN) IC packages.

11. The method of claim 1, further comprising fabricating the IC dies.

12. A method for fabricating integrated circuit (IC) packages, the method comprising:
providing an incomplete lead frame portion comprising through-holes;
laser-cutting three-dimensional step features on the incomplete lead frame portion to form a completed lead frame sheet;
coupling a plurality of IC dies to the completed lead frame sheet; and
coupling the completed lead frame sheet and the IC dies to packaging material to form an IC package block comprising the IC packages.

13. The method of claim 12, wherein providing the incomplete lead frame portion comprises:
providing a conductive metal material sheet; and
implementing a punch press on the conductive metal material sheet to form the through-holes in the incomplete lead frame portion, the incomplete lead frame portion having a length and width approximately equal to the conductive metal material sheet and having an approximately uniform thickness.

14. The method of claim 13, wherein laser-cutting the incomplete lead frame portion comprises laser-cutting the incomplete lead frame portion to form the through-holes of the completed lead frame sheet.

15. The method of claim 12, wherein laser-cutting the incomplete lead frame portion comprises forming a groove on a ground pad of the completed lead frame sheet.

16. The method of claim 12, further comprising laser-cutting the IC package block to singulate the IC packages.

17. The method of claim 12, further comprising fabricating the IC dies.

18. A method for fabricating integrated circuit (IC) packages, the method comprising:
providing an incomplete lead frame portion comprising three-dimensional step features;
laser-cutting through-holes in the incomplete lead frame portion to form a completed lead frame sheet;
coupling a plurality of IC dies to the completed lead frame sheet; and
coupling the completed lead frame sheet and the IC dies to packaging material to form an IC package block comprising the IC packages.

19. The method of claim 18, wherein providing the incomplete lead frame portion comprises:
providing a conductive metal material sheet; and
performing an etching process on the conductive metal material sheet to form the three-dimensional step features on the incomplete lead frame portion, the incomplete lead frame portion having a length and width approximately equal to the conductive metal material sheet and having a thickness that varies to define the three-dimensional step features.

20. The method of claim 19, wherein laser-cutting the incomplete lead frame portion comprises laser-cutting the incomplete lead frame portion to form the through-holes of the completed lead frame sheet.

21. The method of claim 18, wherein laser-cutting the incomplete lead frame portion comprises forming at least one of a fused lead and a groove on a ground pad of the completed lead frame sheet.

22. The method of claim 18, further comprising laser-cutting the IC package block to singulate the IC packages.

23. The method of claim 18, further comprising fabricating the IC dies.

24. An integrated circuit (IC) package comprising:
an IC;
a ground pad formed from a lead frame that is provided from part of a completed lead frame sheet, wherein the completed lead frame sheet is formed from laser-cutting an incomplete lead frame portion to provide the completed lead frame sheet, the completed lead frame sheet comprising through-holes and three-dimensional step features;
a plurality of leads formed from the lead frame; and
packaging material that substantially surrounds the IC and a portion of each of the ground pad and the plurality of leads.

25. The IC package of claim 24, wherein the completed lead frame sheet is formed from implementing a punch press on a conductive metal material sheet to form the through-holes in the incomplete lead frame portion, and laser-cutting the incomplete lead frame portion to form the three-dimensional step features of the completed lead frame sheet.

26. The IC package of claim 24, wherein the completed lead frame sheet is formed from laser-cutting a conductive metal material sheet to form the three-dimensional step features in the incomplete lead frame portion, and etching the incomplete lead frame portion to form the through-holes of the completed lead frame sheet.

27. The IC package of claim 24, wherein the IC package is arranged as a quad flat no-lead (QFN) IC package.

28. The IC package of claim 24, wherein the IC package is formed as one of a plurality of singulated IC packages from an IC package block, the IC package block being laser-cut to provide the plurality of singulated IC packages.
